(19) United States
(12) Patent Application Publication
(10) Pub. No.: US 2003/0127717 A1
(43) Pub. Date: Jul. 10, 2003

(54) Multi-chip stacking package

(76) Inventor: Jen-Kuang Fang, Kaoshiung (TW)

Correspondence Address: Harold V. Stotland, Seyfarth Shaw, 42nd Floor, 55 East Monroe Street, Chicago, IL, 60603-5803, US

(21) Appl. No.: 10/337,577

(22) Filed: Jan. 7, 2003

(30) Foreign Application Priority Data
Jan. 9, 2002 (TW) 091100185

(51) Int. Cl. H01L 23/02

(52) U.S. Cl. 257/678

(57) ABSTRACT

The present invention discloses a multi-chip stacking package, which comprises at least two chips, namely a first chip having a smaller area and a second chip having a larger area. The second chip is combined with a substrate in wire-bonding manner, and the first chip is fixed on the passive surface of the second chip. The passive surface of the second chip are further configured with a plurality of intermediate pads, which are metal pads in a certain fixed type, and the bonding wires from the first chip to the substrate are connected in two sections and with two operations.

### BACKGROUND OF THE INVENTION

1. Field of the Invention

The present invention relates to a multi-chip stacking package, more specifically, to a package using flip-chip bonding and wire-bonding technique to complete the chip stacking.

2. Background of the Invention

For the increasing requirement of high portability of the electronic consumer product, all kinds of functions are integrated. Undoubtedly, the packaging technique of the multi-chip module is one of the best ways to satisfy the requirement. Nevertheless, in order to integrate the functions of multiple chips and reduce the area occupied by the package, such techniques mostly need to stack the chips as a package with three-dimensional structure.

FIG. 1 illustrates a cross-sectional view of a prior multi-chip stacking package 10. The package 10 is characterized in that a plurality of bumps 14 are formed on the active surface of the second chip 12 and are welded to the upper surface of the substrate 16, and that a first chip 11 is fixed on the passive surface of the second chip 12 via an adhesive 18. The active surface of the first chip 11 is provided with a plurality of bonding pads, which are connected to the pads of the substrate 16 with a plurality of bonding wires 13. An encapsulant 19 is covered on the upper surface of the substrate 16 to protect the first chip 11, the second chip 12 and bonding wires 13. The bonding wires 13 of the prior package 10 are required to cross the total depth of the two-chip stacking, so that the arc length is longer and is subject to the external force causing the sweeping, and further the arcs will be in contact with each other to form a short circuit or be cut off at both ends to form an open circuit. Moreover, the central portion of the bonding wires 13 is close to the edge of the second chip 12, so that the arcs will sag due to insufficient tension and possibly contact the edge of the second chip 12 and thus cause a short circuit. The above-mentioned external force possibly comes from the mold flowing pressure by the mold pressing and from the improper vibration causing by the substrate transmission before the mold pressing or from the inappropriate force by manual substrate pick-up.

In order to solve the above-mentioned problem, it is provided with a two-stage wire-bonding method, as shown in FIG. 2. This technique is to generate a plurality of contacts 21 on the passive surface of the second chip 12, wherein these contacts 21 are located around the second chip 12 and are not covered by the first chip 11, and the first bonding wires 22 are used to connect the bonding pad of the first chip 11 to those contacts 21, and the second bonding wires 23 are used to connect the contacts 21 to the bonding pad of the substrate 16. The two layers of bonding wires are employed as a relay race to reduce the length of each arc, so as to prevent these problems for the arc as previously described. Nevertheless, the prior technique only illustrates the idea of the contacts, but does not describe in details how the contacts 21 are created or which distribution type was used to accomplish, so that it is hard to be realized and implemented.

### SUMMARY OF THE INVENTION

The first object of the present invention is to provide a multi-chip stacking package, so as to reduce the occurrence of problems for the arcs and improve the entire yield for the manufacture of the package.

The second object of the present invention is to provide a shape design and positional layout for the intermediate contacts of the bonding wires.

To this end, the present invention discloses a multi-chip stacking package, which comprises at least two chips, namely a first chip having a smaller area and a second chip having a larger area. The second chip is combined with a substrate in wire-bonding manner, and the first chip is fixed on the passive surface of the second chip. The passive surface of the second chip are further configured with a plurality of intermediate pads, which are metal pads in a certain fixed type, and the bonding wires from the first chip to the substrate are connected in two sections and with two operations.

### BRIEF DESCRIPTION OF THE DRAWINGS

The invention will be described according to the appended drawings, in which:

FIG. 1 shows a cross-sectional diagram of a prior multi-chip stacking package;

FIG. 2 shows another cross-sectional diagram of a prior multi-chip stacking package;

FIG. 3 shows a cross-sectional diagram of one embodiment of a multi-chip stacking package according to the invention;

FIG. 4 shows a perspective top view of a multi-chip stacking package according to the invention; and

FIG. 5 shows a schematic diagram of wire bonding between intermediate pads according to the invention.

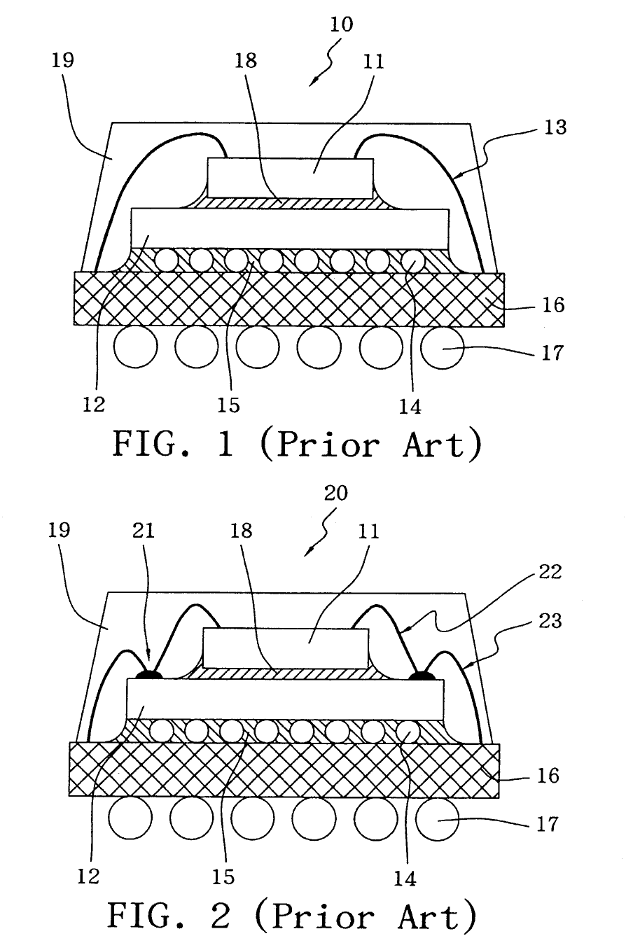

### DESCRIPTION OF PREFERRED EMBODIMENTS

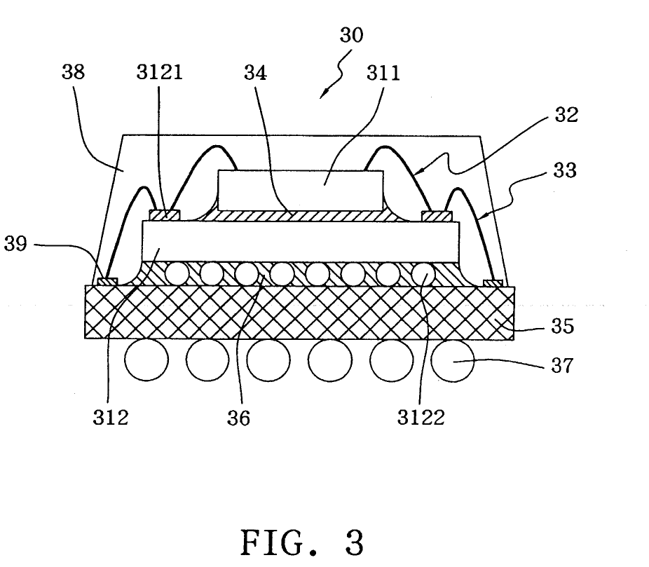

FIG. 3 illustrates a cross-sectional view of a multi-chip stacking package according to the present invention. The package 30 is to fix the first chip 211 in smaller area on the second chip 312 with the adhesive 34, and these two chips are bonded together with their passive surfaces. Moreover, the active surface of the second chip 312 is provided with a plurality of bumps 3122, and the second chip 312 is bonded on the upper surface of the substrate 35 through the processing of flip-chip bonding. Further, a plurality of the intermediate pads 3121 are provided around the passive surface of the second chip 312, and the intermediate pads 3121 are not covered by the first chip 311. Further, a plurality of first bonding wires 32 are used to connect the pads of the first chip 311 and the intermediate pads 3121, and a plurality of second bonding wires 33 are used to connect the intermediate pads 3121 and the pads 39 of the substrate 35. Each intermediate pad 3121 is configured with the bonds of the first bonding wires 32 and the second bonding wires 33. The upper surface of the substrate 35 is covered with an encapsulant 38, which can protect the stacked chip structure and the bonding wires on the upper and lower layers. The lower surface of the substrate 35 is configured with a plurality of solder balls 37, and each solder ball 37 is served as an electrical contact with an external system.

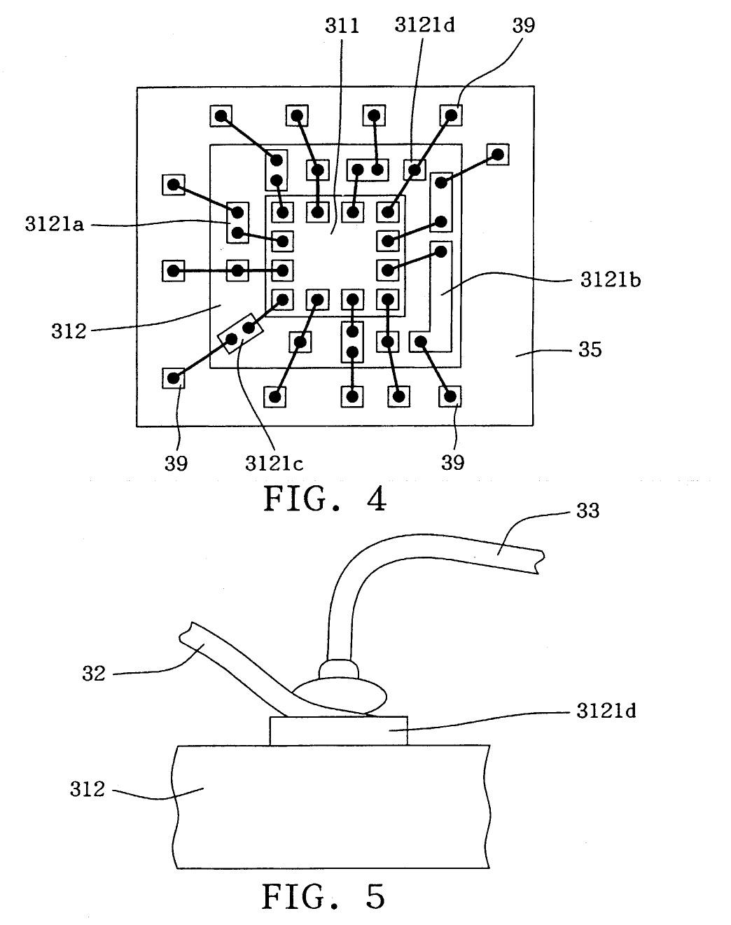

FIG. 4 is a perspective top view of a multi-chip stacking package according to the present invention, which illustrates a direct perspective view on the upper surface of the substrate 35 by removing the encapsulant 38. In particular, there are various types of the intermediate pad 3121 of the second chip 312, such as that the area of the intermediate pad 3121a is able to accommodate two bonds; the intermediate pad 3121b is of irregular shape to be beneficial to the convenience of the wiring bonding operation and to simplify the circuit trace of the substrate 35; the intermediate pad 3121c is similar to the 3121a, but with an angle that can be adjusted in response to the wire-bonding operation; the intermediate pad 3121d is a pad only for one contact capability. FIG. 5 shows an embodiment of wire bonding between the intermediate pads 3121d. In this figure, the wedge bonds of the first bonding wires 32 are directly bonded with the intermediate pad 3121d, and the ball bonds of the second bonding wires 33 are over-welded on the wedge bonds of the first bonding wires 32.

The intermediate pad 3121 is a type of bonding pad formed on the back of the second chip 312, or referred to as the dummy pad, which uses a semiconductor process to deposit the metal layer on the back of the wafer and uses the etching process to reserve the pattern of designed contacts. The metal layer may use an Under Bump Metallurgy (UBM) process, which is similar to the flip-chip bump process for attaching the same metal material on the back of the wafer.

The above-described embodiments of the present invention are intended to be illustrated only. Numerous alternative embodiments may be devised by persons skilled in the art without departing from the scope of the following claims.

What is claimed is:

1. A multi-chip stacking package, comprising:
a first chip;
a second chip including:
an active surface;
an inactive surface for mounting said first chip thereon; and
a plurality of pads formed at a periphery of said inactive surface by a semiconductor process;
a substrate flip-chip bonding to said active surface of said second chip;
a plurality of first bonding wires for electrically connecting to said first chip and said pads; and
a plurality of second bonding wires for electrically connecting to said pads and said substrate.

2. The multi-chip stacking package of claim 1, further comprising an encapsulant covering said first chip, said second chip, said first bonding wires, said second bonding wires and an upper surface of said substrate.

3. The multi-chip stacking package of claim 1, further comprising a plurality of solder balls on a lower surface of said substrate.

4. The multi-chip stacking package of claim 1, wherein said pads are under bump metallurgies.

5. The multi-chip stacking package of claim 1, wherein the plurality of pads are of rectangle, polygon, circle or irregular enclosed shapes.

6. The multi-chip stacking package of claim 1, wherein contacts for electrically connecting the plurality of pads and said first bonding wires are overlapped with contacts for electrically connecting the plurality of pads and said second bonding wires.
